(19) United States
(12) Patent Application Publication
(10) Pub. No.: US 2014/0353744 A1
(43) Pub. Date: Dec. 4, 2014

(54) SEMICONDUCTOR DEVICE

(71) Applicant: SK hynix Inc., Gyeonggi-do (KR)

(72) Inventors: Ho-Jin JUNG, Gyeonggi-do (KR); Chang-Heon PARK, Gyeonggi-do (KR); Dong-Goo CHOI, Gyeonggi-do (KR); Joong-Gun YOO, Gyeonggi-do (KR); Yeo-Jin YOON, Gyeonggi-do (KR); Seong-Hwan AHN, Gyeonggi-do (KR); Jin-Wook CHEONG, Gyeonggi-do (KR)

(73) Assignee: SK hynix Inc., Gyeonggi-do (KR)

(21) Appl. No.: 14/057,923

(22) Filed: Oct. 18, 2013

(30) Foreign Application Priority Data
May 31, 2013 (KR) 10-2013-0062991

(51) Int. Cl. H01L 29/78

(52) U.S. Cl. CPC H01L 29/7827
USPC 257/330

(57) ABSTRACT

A semiconductor device includes a substrate including a first active region and second active regions, a bit line structure in contact the first active region, and storage node contacts in contact the second active regions. A top surface of the first active region is lower than the top surfaces of the second active regions.

### CROSS-REFERENCE TO RELATED APPLICATIONS

The present application claims priority of Korean Patent Application No. 10-2013-0062991, filed on May 31, 2013, which is incorporated herein by reference in its entirety.

### BACKGROUND

1. Field

Exemplary embodiments of the present invention relate to a semiconductor fabrication technology, and, more particularly, to a semiconductor device including a buried gate and a method for fabricating the same.

2. Description of the Related Art

As a semiconductor device becomes increasingly miniaturized, it has become difficult to implement characteristics and fabrication of the device. In particular, the sub-40 nm process has a limitation in forming a gate, a bit line, a contact, and other like components. Further, there are difficulties in securing a desired characteristic of the device fabricated in the sub-40 nm process. Thus, a buried gate, which is a gate buried in a substrate, has been recently adopted.

### SUMMARY

Various embodiments of the present invention are directed to a semiconductor device and a method for fabricating the same that may prevent a short between a storage node contact and an adjacent active region.

Also, various embodiments of the present invention are directed to a semiconductor device and a method for fabricating the same that may prevent a short between a buried gate and a bit line contact.

In an exemplary embodiment of the present invention, a semiconductor device includes a substrate including a first active region and second active regions, a bit line structure in contact with the first active region, and storage node contacts in contact with the second active regions, wherein a top surface of the first active region is lower than top surfaces of the second active regions.

The bit line structure may include a bit line contact, a bit line electrode, and a bit line hard mask, and may further include spacers—the spacer being formed on sidewalls of the bit line structure.

The first active region may be disposed between adjacent second active regions.

In another exemplary embodiment of the present invention, a semiconductor device includes a substrate including buried gate structures, a first active region formed between the buried gate structures and second active regions, the second active regions in contact with one side of the buried gate structures and arranged symmetrically with each other, a bit line structure in contact with the first active region, and storage node contacts in contact with the second active regions, wherein a top surface of the first active region is lower than top surfaces of the second active regions and top surfaces of the buried gate structures.

The buried gate structures may include a stacked structure of a buried gate electrode and a sealing layer, and the top surface of the sealing layer may be positioned at a higher level than the bottom surface of the first active region.

In still another exemplary embodiment of the present invention, a method for fabricating a semiconductor device includes forming a first insulating layer over a substrate including a first active region and a second active region, etching a first region of the first insulating layer to form a bit line contact hole through which the first active region is exposed, forming a bit line structure that is partially buried in the bit line contact hole and protrudes from a top of the first insulating layer, forming a second insulating layer over the first insulating layer including the bit line structure, and etching the second insulating layer and a second region of the first insulating layer to form a storage node contact hole through which the second active region is exposed, wherein a top surface of the first region is lower than a top surface of the second active region.

The etching of the first region of the first insulating layer may include over-etching the first active region so that the top surface of the first active region is lower than the top surface of the second active region.

The over-etching of the first active region may be performed under a condition in which an etch rate of oxide and nitride is higher than an etch rate of silicon.

In still another exemplary embodiment of the present invention, a method for fabricating a semiconductor device includes forming a first insulating layer over a substrate including a buried gate structure, a first active region, and a second active region; etching a first region of the first insulating layer to form a bit line contact hole through which the first active region is exposed; forming a bit line structure that is partially buried in the bit line contact hole and partially protrudes from the top of the first insulating layer; forming a second insulating layer over the first insulating layer including the bit line structure; and etching the second insulating layer and a second region of the first insulating layer to form a storage node contact hole through which the second active region is exposed, wherein a top surface of the first active region is lower than a top surface of the second active region and a top surface of the buried gate structure.

The buried gate structure may include a stacked structure of a buried gate electrode and a sealing layer, and the sealing layer may include nitride.

The etching of the first region of the first insulating layer may be performed under a condition in which an etch rate of silicon is higher than an etch rate of nitride.

The etching of the first region of the first insulating layer is performed through a gas or a mixture of two or more gases, selected from the group consisting of CF₄, CHF₃, CH₃F, and CH₂F₂.

Furthermore, the etching of the first region of the first insulating layer may be performed by further adding a mixture of Ar, He, and O₂ to the gas or the mixture of two or more gases.

In still another exemplary embodiment of the present invention, a semiconductor device includes a substrate including a buried gate structure, a first active region and a second active region, a bit line structure in contact with the first active region and storage node contacts in contact with the second active region, wherein a top surface of the first active region is lower than a top surface of the second active region and a top surface of the buried gate structure.

### BRIEF DESCRIPTION OF THE DRAWINGS

FIG. 1 is a layout illustrating a semiconductor device.

FIG. 2 is a cross-sectional view of a semiconductor device in accordance with an embodiment of the present invention taken along the A-A′ direction illustrated in FIG. 1.

FIG. 3 is a cross-sectional view of a semiconductor device in accordance with an embodiment of the present invention taken along the B-B′ direction illustrated in FIG. 1.

FIGS. 4A to 4J are cross-sectional views illustrating a method for fabricating the semiconductor device in accordance with an embodiment of the present invention taken along the A-A′ direction illustrated in FIG. 1.

FIGS. 5A to 5J are cross-sectional views illustrating the method for fabricating the semiconductor device in accordance with an embodiment of the present invention taken along the B-B′ direction illustrated in FIG. 1.

FIG. 6 is a cross-sectional view of a semiconductor device in accordance with another embodiment of the present invention taken along the A-A′ direction illustrated in FIG. 1.

FIG. 7 is a cross-sectional view of a semiconductor device in accordance with another embodiment of the present invention taken along the B-B′ direction illustrated in FIG. 1.

FIGS. 8A to 8J are cross-sectional views illustrating a method for fabricating the semiconductor device in accordance with another embodiment of the present invention taken along the A-A′ direction illustrated in FIG. 1.

FIGS. 9A to 93 are cross-sectional views illustrating the method for fabricating the semiconductor device in accordance with another embodiment of the present invention taken along the B-B′ direction illustrated in FIG. 1.

### DETAILED DESCRIPTION

Various embodiments will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, reference numerals correspond directly to the like numbered parts in the various figures and embodiments of the present invention.

The drawings are not necessarily to scale and, in some instances, proportions may have been exaggerated in order to clearly illustrate features of the embodiments. It should be readily understood that the meaning of “on” and “over” in the present disclosure should be interpreted in the broadest manner such that “on” means not only “directly on” but also “on” something with an intermediate feature(s) or a layer(s) therebetween, and that “over” means not only directly on top but also on top of something with an intermediate feature(s) or a layer(s) therebetween. It is also noted that, in this specification, “connected/coupled” refers to one component not only directly coupling another component but also indirectly coupling another component through an intermediate component. In addition, a singular form may include a plural form as long as it is not specifically mentioned in a sentence.

Recently, a short between a storage node contact and an adjacent active region has emerged as a troublesome concern in semiconductor fabrication, which is becoming increasingly serious as a distance between the storage node contact and the adjacent active region is becoming reduced making it more difficult to secure a process margin. In order to increase the distance between the storage node contact and the adjacent active region, a critical dimension (CD) of at least one of the storage node contact and the active region may be reduced. In this case, however, when a storage node contact hole is formed, a “NOT OPEN” phenomenon may occur. Furthermore, the reduction in CD of the storage node contact or active region may cause a bad influence on semiconductor device characteristics.

As the design rule shrinks, a contact plug fabrication process, in which no spacer is used, is applied to secure the CD of a bit line contact. However, if no spacer is applied to the bit line contact, a distance between a buried gate and the bit line contact may be reduced, and, thus, a short may occur due to a misalignment or an abnormal unetch of the buried gate. Since such a defect may not be detected during a probe test, a finalized device is likely to have a defect. The embodiments of the present invention provide a semiconductor device and a method for fabricating the same, which may prevent a short between the storage node contact and the adjacent active region and may prevent a short between the buried gate and the bit line contact

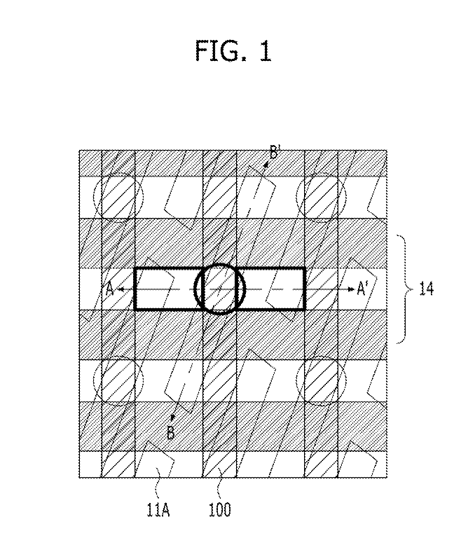

FIG. 1 is a layout illustrating a semiconductor device.

Referring to FIG. 1, a plurality of first active regions 11A, each of which is formed in an oblique direction, are repetitively arranged with a predetermined margin therebetween. The first active regions 11A are defined by an isolation layer (not illustrated).

A plurality of buried gate electrodes 14 are formed to cross the first active regions 11A, respectively. A plurality of bit line structures 100, each of which is extended in a direction crossing the buried gate electrodes 14, are formed over a substrate (not illustrated).

The bit line structures 100 and the first active regions 11A are connected through bit line contacts (not illustrated), and storage node contacts (not illustrated) are formed at both sides of the bit line contacts to connect to the first active regions 11A.

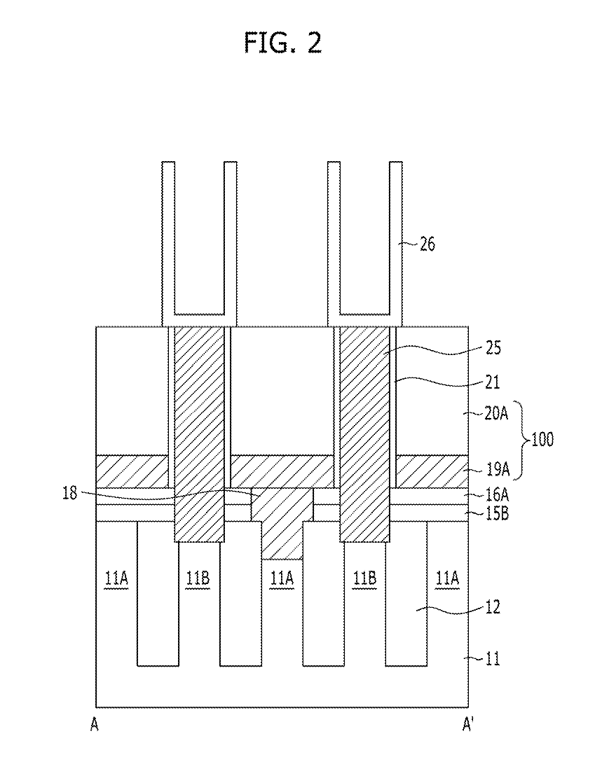

FIG. 2 is a cross-sectional view of a semiconductor device in accordance with an embodiment of the present invention taken along the A-A′ direction illustrated in FIG. 1.

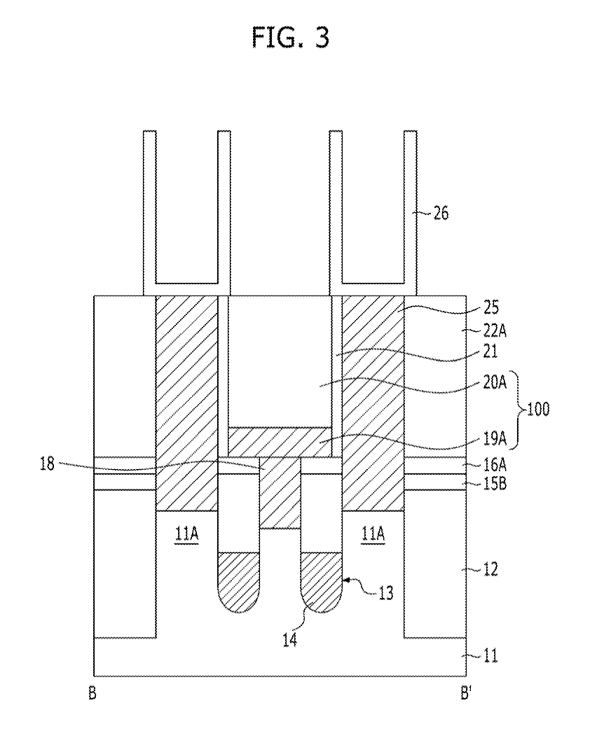

FIG. 3 is a cross-sectional view of a semiconductor device in accordance with an embodiment of the present invention taken along the B-B′ direction illustrated in FIG. 1.

Referring to FIGS. 2 and 3, an isolation layer 12 is formed in a semiconductor substrate 11 to define active regions 11A and 11B. The active regions 11A and 11B may be referred to as the first active region 11A and a second active region 11B, respectively. The first active region 11A may be disposed between a pair of second active regions 11B. The semiconductor substrate 11 may be a buried gate structure (not illustrated formed therein. The buried gate structure may include a stacked structure of a buried gate electrode (not illustrated) and a sealing layer 15B. The sealing layer 15B may also be formed over the semiconductor substrate 11. A hard mask pattern 16A may be formed over the sealing layer 15B to open a region corresponding to a first plug 18.

A bit line structure 100 may be formed to contact the first active region 11A, and a second plug 25 may be formed to contact the second active region 11B. The bit line structure 100 may include a stacked structure of a bit line electrode 19A and a bit line hard mask 20A. The bit line structure 100 may further include the first plug 18 and a spacer 21 formed on sidewalls of the bit line electrode 19A and the bit line hard mask 20A. The first plug 18 may include a bit line contact, connecting the bit line electrode 19A and the first active region 11A, and the spacer 21 may insulate the second plug 25 formed between the bit line structures 100. Furthermore, an insulating layer 22A may be formed to fill the space between the bit line structures 100.

The second plug 25 is formed between the bit line structures 100 to contact the second active region 11B through the sealing layer 15B and the hard mask pattern 16A. The second plug 25 may include a storage node contact. In this embodiment, a pair of second plugs 25 may be formed to contact a pair of second active regions 11B, respectively. The top surface of the first active region 11A may be lower than the top surface of the second active region 11B. Thus, a margin between the second plug 25 and the adjacent first active region 11A may be secured to prevent a short.

A storage electrode 26 may be formed to be connected to the second plug 25. The storage electrode 26 may include a stacked structure of a bottom electrode, a dielectric layer, and a top electrode.

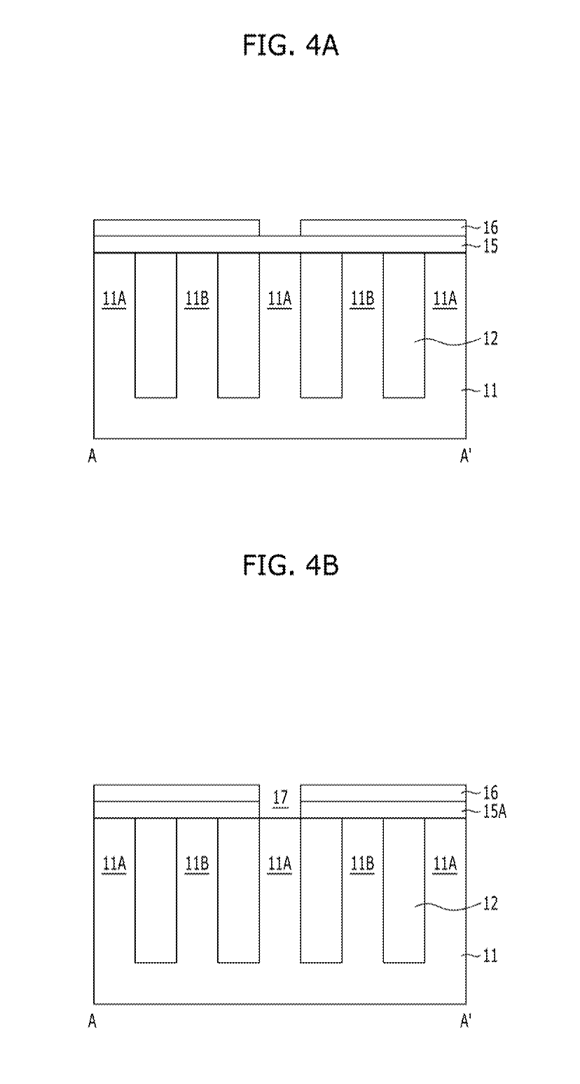

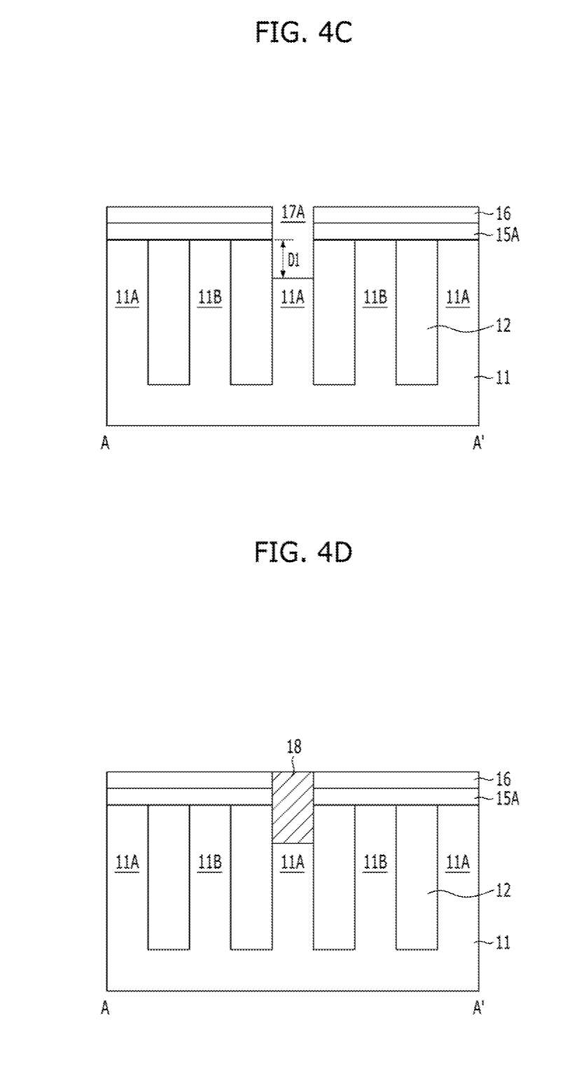

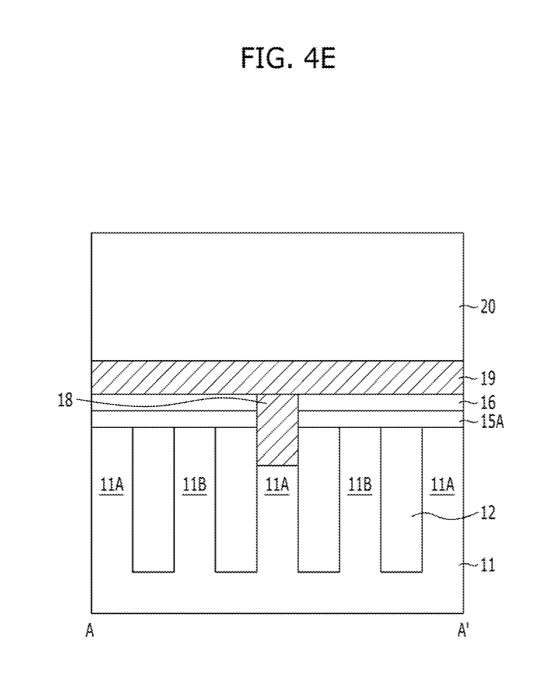

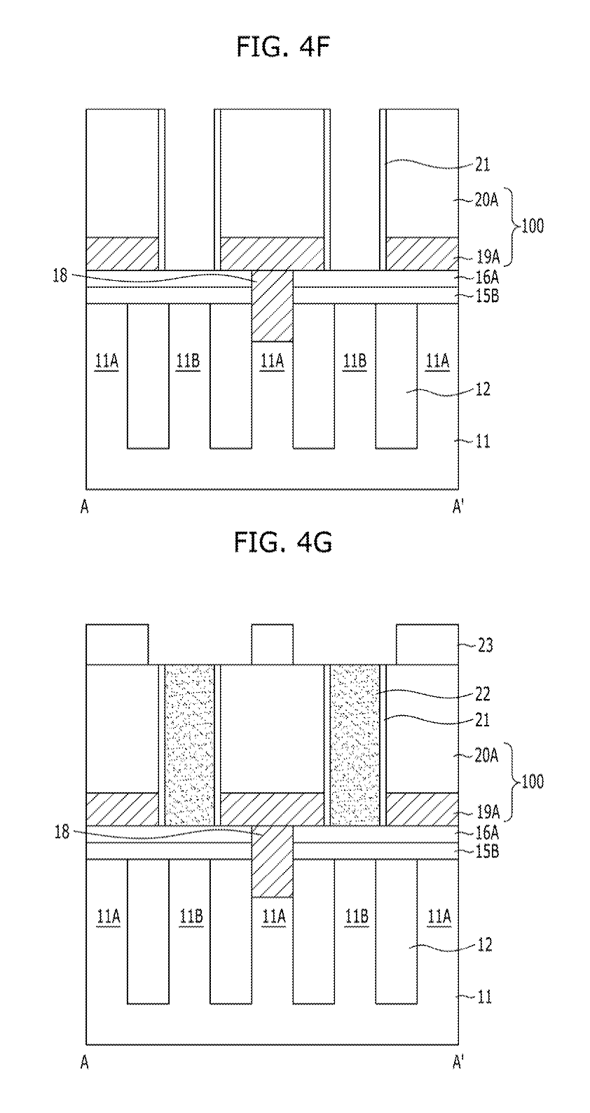

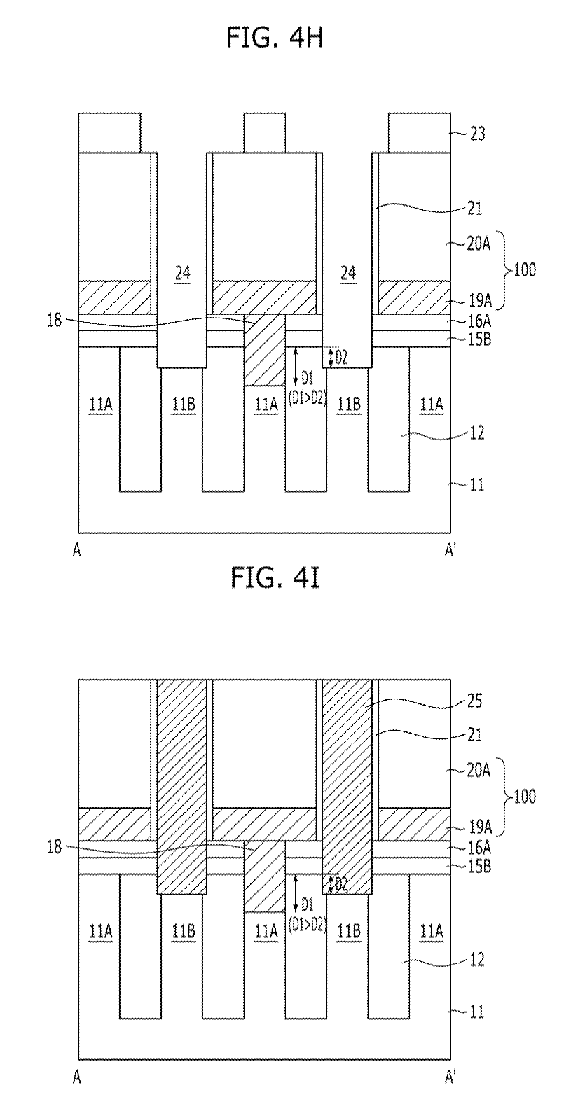

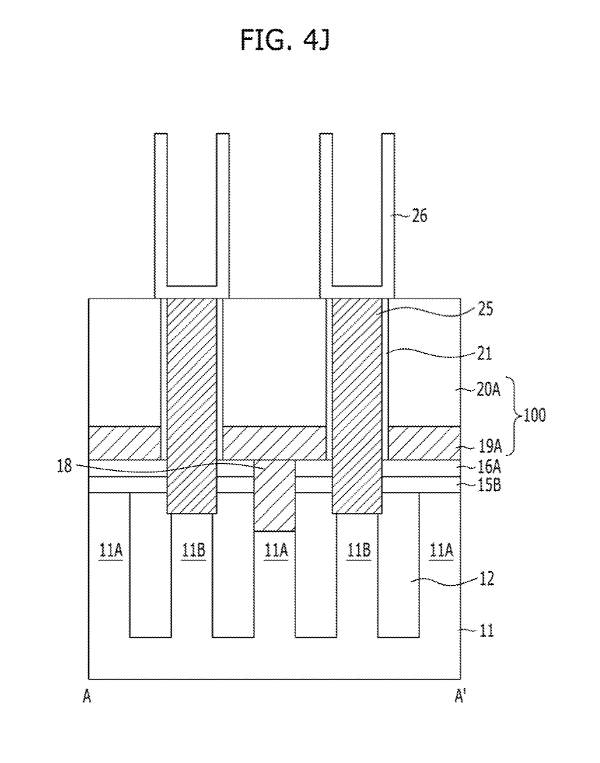

FIGS. 4A to 4J are cross-sectional views illustrating a method for fabricating the semiconductor device in accordance with an embodiment of the present invention taken along the A-A′ direction illustrated in FIG. 1.

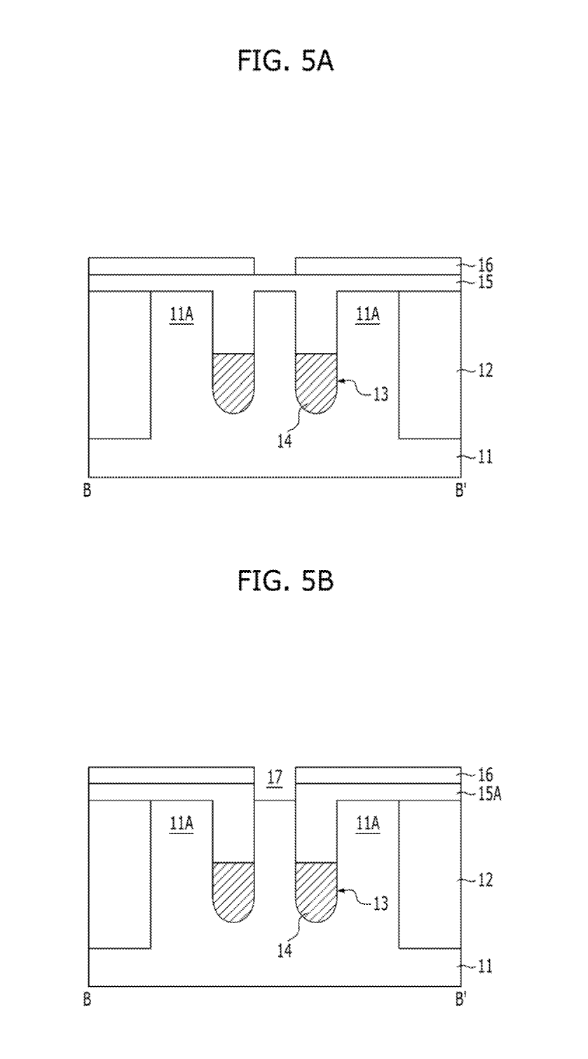

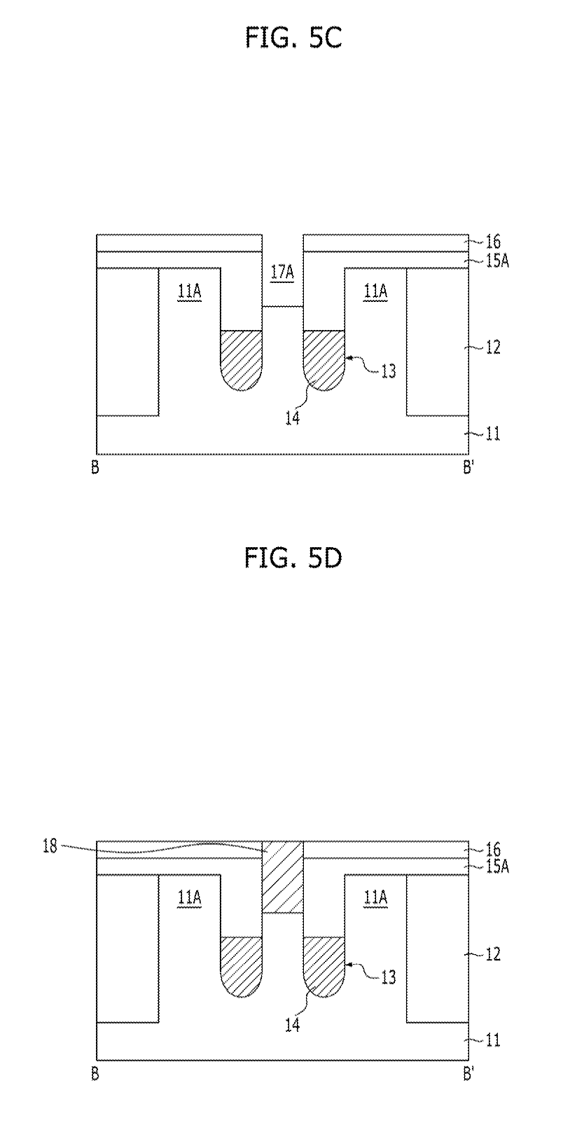

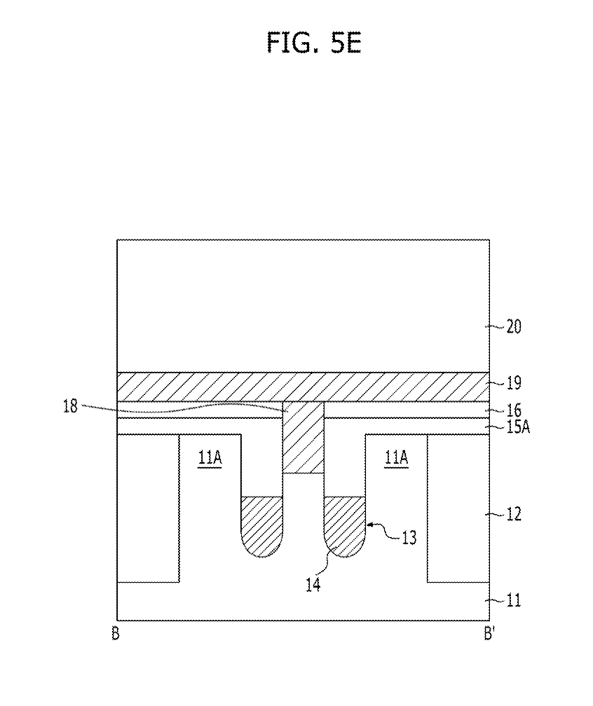

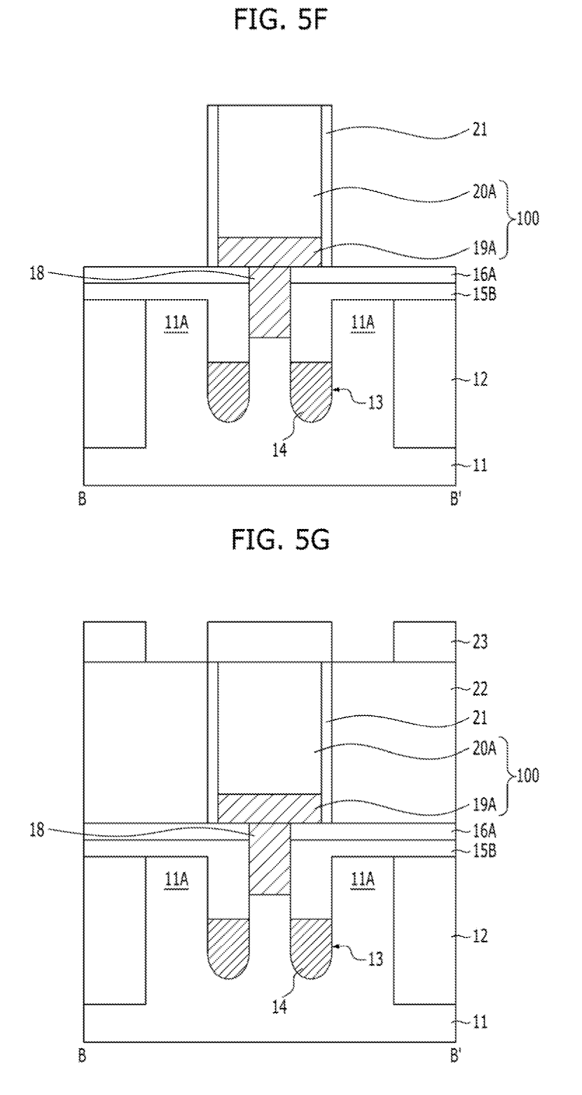

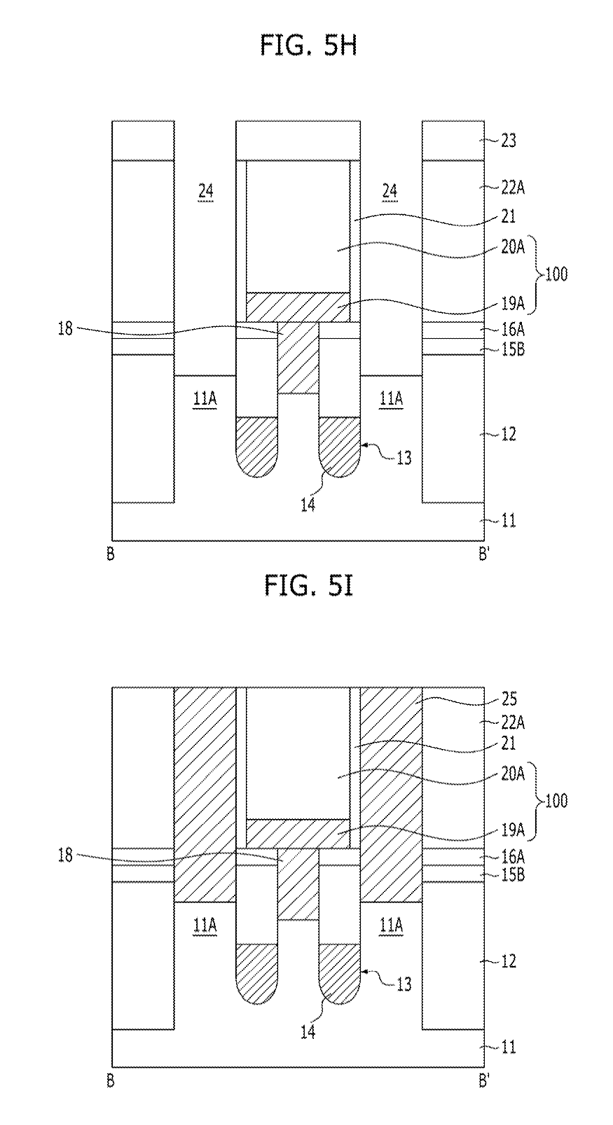

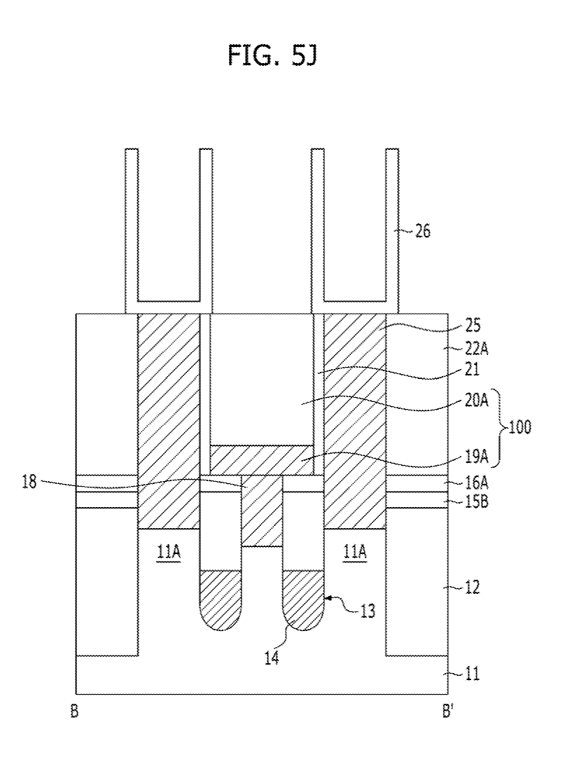

FIGS. 5A to 5J are cross-sectional views illustrating the method for fabricating the semiconductor device in accordance with an embodiment of the present invention taken along the B-B′ direction illustrated in FIG. 1.

In order to promote a better understanding, FIGS. 4A to 4J and FIGS. 5A to 5J will be described together. The steps of FIGS. 4A to 4J and the steps of FIGS. 5A to 5J are performed according to the same process sequence, and like reference numerals refer to like components.

Referring FIGS. 4A and 5A, the isolation layer 12 is formed in the semiconductor substrate 11 to define active regions 11A and 11B. The semiconductor substrate 11 may be a silicon substrate or a silicon germanium substrate. The isolation layer 12 may be formed through the shallow trench isolation (STI) process.

Then, the semiconductor substrate 11 is etched to form a trench 13. The trench 13 serves to provide the buried gate formation region. A pair of trenches 13 may be formed. The active region 11A is disposed between the pair of trenches 13, and the active region 11B is disposed between the trench 13 and the isolation layer 12. That is, the first active region 11A may be disposed between the pair of trenches 13 and between the pair of second active regions 11B.

A buried gate electrode 14 is formed to fill a part of the trench 13. Before the buried gate electrode 14 is formed, a gate dielectric layer (not illustrated) may be formed on the sidewalls and bottom of the trench 13.

The buried gate electrode 14 may be formed through the following process: a conductive material is formed to fill the trench 13, planarized until the semiconductor substrate 11 is exposed, and then recessed to a predetermined depth. The conductive material may serve as an electrode. The conductive material may be a low-resistance material such as tungsten, for example. Alternatively, the conductive material may be a stacked structure of a diffusion barrier layer and a metal layer. For example, the diffusion barrier layer may be a titanium-containing material, and the metal layer may be a low resistance metal. The titanium containing material may be TiN, for example.

A sealing layer 15 is formed over the buried gate electrode 14 to fill the rest of the trench 13. The sealing layer 15 serves to protect the buried gate electrode 14 from being oxidized and attacked during a subsequent process and may include an insulating material. For example, the sealing layer 15 may be a nitride material. The sealing layer 15 may be formed to such a thickness as to fill the trench 13 and may be formed even over the semiconductor substrate 11. As disclosed above, together the buried gate electrode 14 and the sealing layer 15 define the buried gate structure.

A hard mask pattern 16 is formed over the sealing layer 15. The hard mask pattern 16 is patterned to open a bit line contact region. That is, the hard mask pattern 16 may be patterned to define a bit line contact hole, and the bit line contact region may include an active region between the adjacent buried gate electrodes 14. The hard mask pattern 16 may be an insulating material having an etching selectivity with respect to the sealing layer 15 and the semiconductor substrate 11. For example, the hard mask pattern 16 may be an oxide material such as silicon oxide.

Referring to FIGS. 4B and 5B, a first contact hole 17 is formed by etching the sealing layer 15 using the hard mask pattern 16 as an etch barrier. The first contact hole 17 may include a region for forming a bit line contact hole. The etching process for forming the first contact hole 17 may be performed until the first active region 11A is exposed.

The etched sealing layer 15 is represented by reference numeral 15A.

Referring to FIGS. 4C and 5C, the first active region 11A exposed at the bottom of the first contact hole 17 is etched to a predetermined depth D₁. The etching process may be performed to such a depth as not to expose the buried gate electrode 14. The depth D₁ of the first contact hole 17 may be defined in consideration of a thickness loss of the semiconductor substrate 11 when a storage node contact hole is formed during a subsequent process. The depth of the first contact hole 17 may be larger than the thickness of the semiconductor substrate 11 that may be lost when the storage node contact hole is formed.

The first contact hole 17A having a larger depth is formed due to etching of the first active region 11A.

Referring to FIGS. 40 and 5D, the first plug 18 is formed to fill the first contact hole 17A and to contact the first active region 11A. The first plug 18 may include the bit line contact for connecting the semiconductor substrate 11 and the bit line structure that is to be subsequently formed. The first plug 18 may be a conductive material.

Referring to FIGS. 4E and 5E, a conductive layer 19 is formed over the first plug 18 and the hard mask pattern 16. In an embodiment, the first plug 18 and the conductive layer 19 are formed separately from each other. In another embodiment, the first contact hole 17A of FIG. 4C may also be filled with the conductive layer 19 instead of the first plug 18. The conductive layer 19 filled in the first contact hole 17A and over the hard mask pattern 16 may form the first plug 18 and the bit line electrode 19A.

A bit line hard mask layer 20 is formed over the conductive layer 19. The bit line hard mask layer 20 may serve as an etch barrier and an insulating layer between an upper layer and a bit line during a bit line formation process. The bit line hard mask layer 20 may be a nitride material such as silicon nitride.

Referring to FIGS. 4F and 5F, the bit line hard mask layer 20 and the conductive layer 19 illustrated in FIGS. 4E and 5E are etched to form a bit line structure 100. The etched bit line hard mask layer 20 and the etched conductive layer 19 define the bit line hard mask 20A and the bit line electrode 19A, respectively. Together the bit line hard mask 20A and the bit line electrode 19A define the bit line structure 100.

The spacer 21 is formed on the sidewalls of the bit line structure 100. The spacer 21 may serve to protect the sidewalls of the bit line structure 100 and serve as an insulating layer between storage node contacts that are to be subsequently formed. For example, the spacer 21 may be an insulating material or a nitride material such as silicon nitride.

Referring to FIGS. 4G and 5G an interlayer dielectric layer 22 is formed to fill the space between the bit line structures 100. The interlayer dielectric layer 22 may be formed through the following process: an insulating material is formed to fill the space between the bit line structures 100 and then planarized until the top surface of the bit line structure 100 is exposed. The planarization may be performed through a chemical mechanical polishing (CMP) process or an etch-back process. The insulating material may be an oxide material such as silicon oxide.

A mask pattern 23 is formed over the bit line structure 100 and the interlayer dielectric layer 22. The mask pattern 23 may be formed by applying a photoresist layer onto the bit line structure 100 and the interlayer dielectric layer 22 and by patterning the photoresist layer through exposure and development to open a storage node contact region. In the A-A′ direction, where a margin between the storage node contacts is small, the mask pattern 23 may be formed with a larger CD than the CD of the space between the bit line structures 100.

Referring to FIGS. 4H and 5H, a second contact hole 24 that exposes the second active region 11B is formed by selectively etching the interlayer dielectric layer 22, the hard mask pattern 16, and the sealing layer 15A between the bit line structures 100 using the mask pattern 23 as an etching barrier. The second contact hole 24 may be the storage node contact hole for forming a storage node contact.

In the A-A′ direction, where the mask pattern 23 is formed with a larger CD than the CD of the space between the bit line structures 100, the bit line hard mask 20A made of nitride may be used as an etch barrier to perform a self-aligned contact etch process. The self-aligned contact etch process refers to an etch process using a gas that selectively etches, for example, only oxide while having an etching selectivity with respect to nitride. Thus, for example, only the interlayer dielectric layer 22 may be selectively etched without a loss of the bit line hard mask 20A. In order to form the second contact hole 24 that exposes the second active region 11B, the sealing layer 15A made of nitride and formed over the semiconductor substrate 11 is etched. However, since the sealing layer 15A is sufficiently thin, loss of the bit line hard mask 20A is not serious.

When the second contact hole 24 is formed, the second active region 11B of the semiconductor substrate 11 may be additionally etched to a predetermined depth D₂ in order to reduce interfacial resistance between the storage node contact and the second active region 11B. When the second active region 11B is additionally etched, a contact area between the storage node contact and the second active region 11B may increase while the bottom and sidewalls of the storage node contact partially contact the second active region 11B. Thus the interfacial resistance may be reduced.

The depth D₂ to which the second active region 11B is additionally etched may be adjusted not to exceed the depth D₁ to which the first active region 11A is additionally etched when the bit line contact hole is formed.

The etched interlayer dielectric layer 22, the etched hard mask pattern 16, and the etched sealing layer 15A are represented by 22A, 16A, and 15B, respectively.

Referring to FIGS. 4I and 5I, the second plug 25 is formed to fill the second contact hole 24. The second plug 25 may be formed through the following process: a conductive material is formed to fill the second contact hole 24 and then planarized until the top surface of the interlayer dielectric layer 22A is exposed. The planarization process may be a CMP process or an etch-back process.

Before the second plug 25 is formed, a spacer (not illustrated) may be additionally formed on the sidewalls of the second contact hole 24.

As the second plug 25 is shallower than the first plug 18 in the semiconductor substrate 11, a margin between the second plug 25 and the first active region 11A adjacent to the bottom surface of the second plug 25 may be secured. Thus, when the second plug 25 is formed, it is possible to prevent a short between the second plug 25 and the adjacent first active region 11A even though a misalignment occurs.

Referring to FIGS. 4J and 5J, a storage electrode 26 is formed over the interlayer dielectric layer 22A to connect to the second plug 25. The storage electrode 26 may include a stacked structure of a bottom electrode, a dielectric layer, and a top electrode. The storage electrode 26 is formed in a cylinder type but may be formed in a pillar type, a concave type, a plate type, or a stack type.

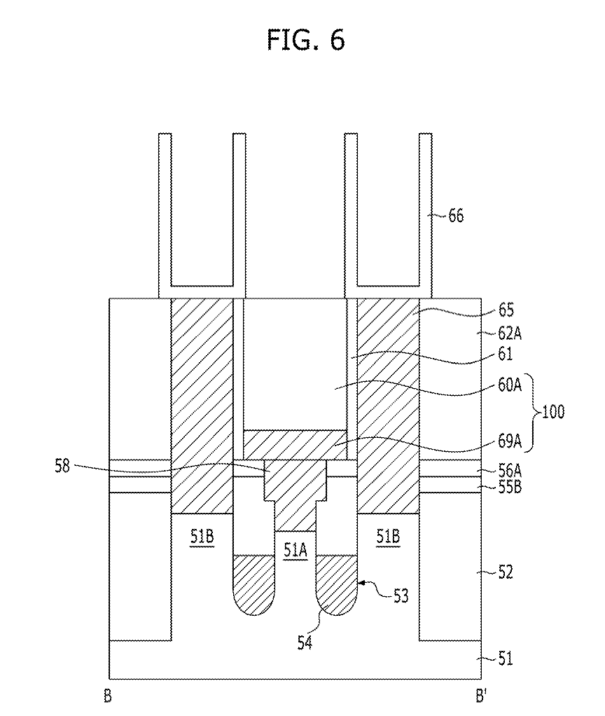

FIG. 6 is a cross-sectional view of a semiconductor device in accordance with another embodiment of the present invention taken along the A-A′ direction illustrated in FIG. 1.

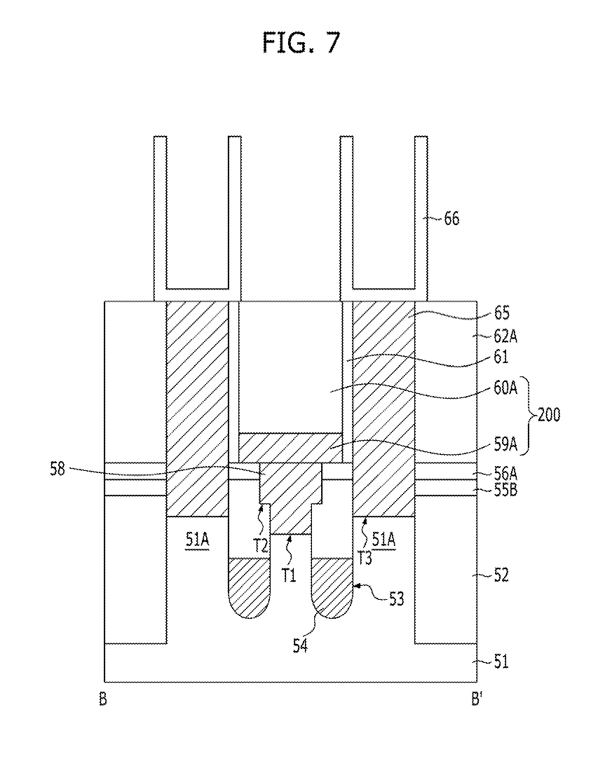

FIG. 7 is a cross-sectional view of a semiconductor device in accordance with another embodiment of the present invention taken along the B-B′ direction illustrated in FIG. 1.

Reference numerals 11A, 14. and 100 of FIGS. 1 to 5 correspond to reference numerals 51A, 54, and 200 of FIGS. 6 to 9, respectively.

Referring to FIGS. 6 and 7, an isolation layer 52 is formed in a semiconductor substrate 51 to define active regions 51A and 51B. The active regions 51A and 51B may be referred to as a first active region 51A and a second active region 51B, respectively. The first active region 51A may be disposed between a pair of second active regions 51B. The semiconductor substrate 51 may be a buried gate structure (not illustrated) formed therein. The buried gate structure may include a stacked structure of a buried gate electrode (not illustrated) and a sealing layer 55B. The sealing layer 55B may also be formed even over the semiconductor substrate 51. Furthermore, a hard mask pattern 56A may be formed over the sealing layer 55B to open a region corresponding to a first plug 58.

A bit line structure 200 may be formed to contact the first active region 51A, and a second plug 65 may be formed to contact the second active region 51B. The bit line structure 200 may include a stacked structure of a bit line electrode 59A and a bit line hard mask 60A. The bit line structure 200 may further include the first plug 58 and a spacer 61 formed on the sidewalls of the bit line electrode 59A and the bit line hard mask 60A. The first plug 58 may include a bit line contact connecting the bit line electrode 59A and the first active region 51A, and the spacer 61 may serve to insulate the second plug 65 formed between the bit line structures 200. Furthermore, an insulating layer 62A may be formed to fill the space between the bit line structures 200.

The second plug 65 is formed between the bit line structures 200 to contact the second active region 516 through the sealing layer 55B and the hard mask pattern 56A. The second plug 65 may include a storage node contact. In this embodiment, a pair of second plugs 65 may be formed to contact a pair of second active regions 51B, respectively. The top surface T1 of the first active region 51A may be lower than the top surface T2 of the buried gate structure and the top surface T3 of the second active region 51B. Thus, a margin between the buried gate electrode 54 and the first plug 58 may be secured, and a margin between the second plug 65 and the first active regions 51A adjacent to the second plug 65 may be secured. Therefore, it is possible to prevent a short in each case.

A storage electrode 66 may be formed to connect to the second plug 65. The storage electrode 66 may include a stacked structure of a bottom electrode, a dielectric layer, and a top electrode.

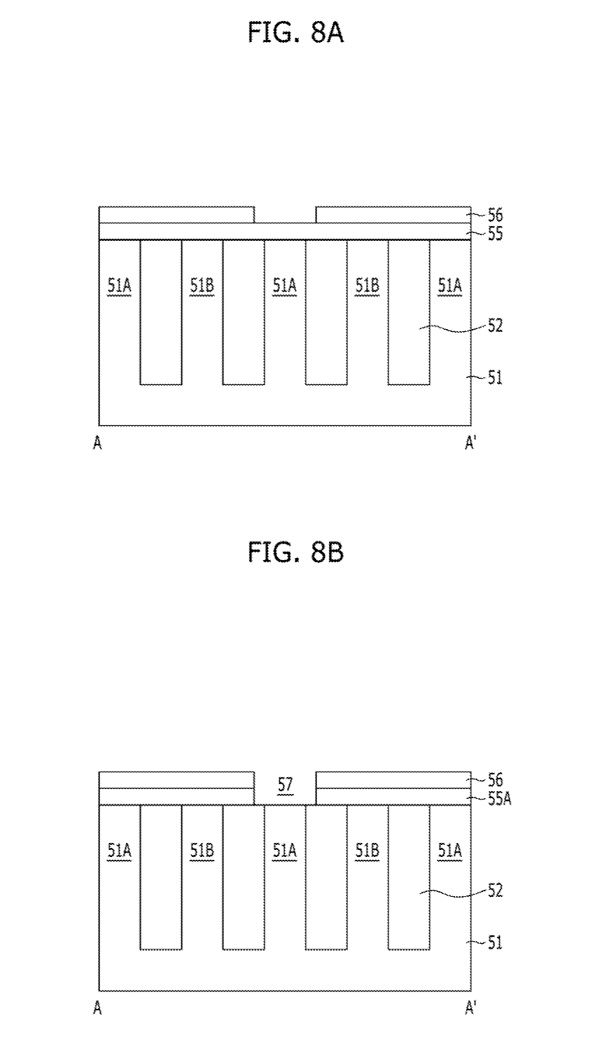

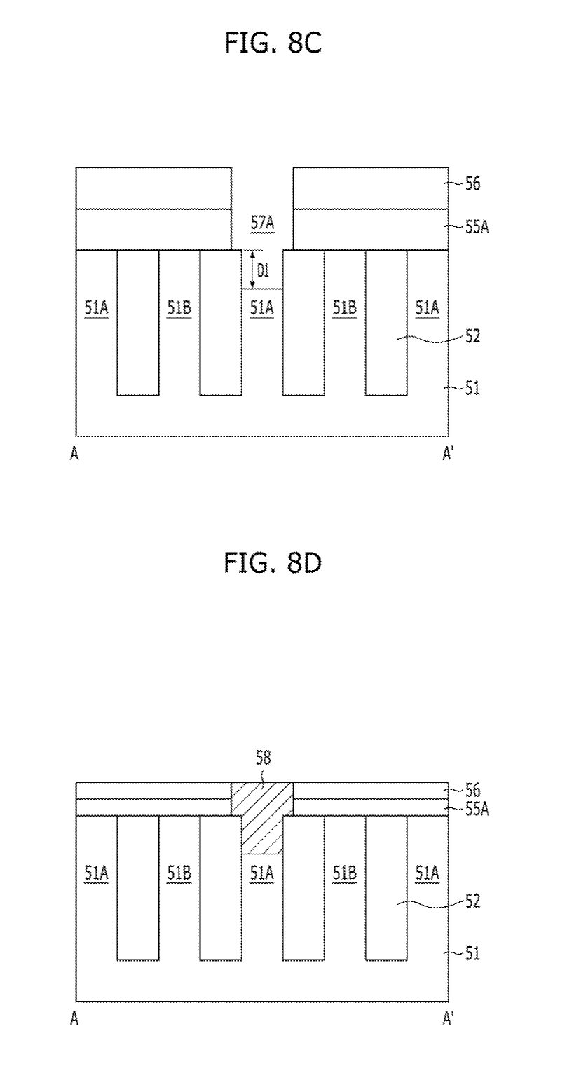

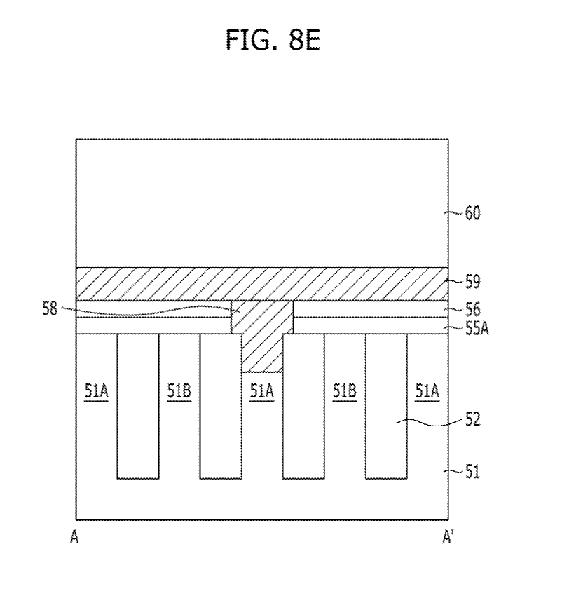

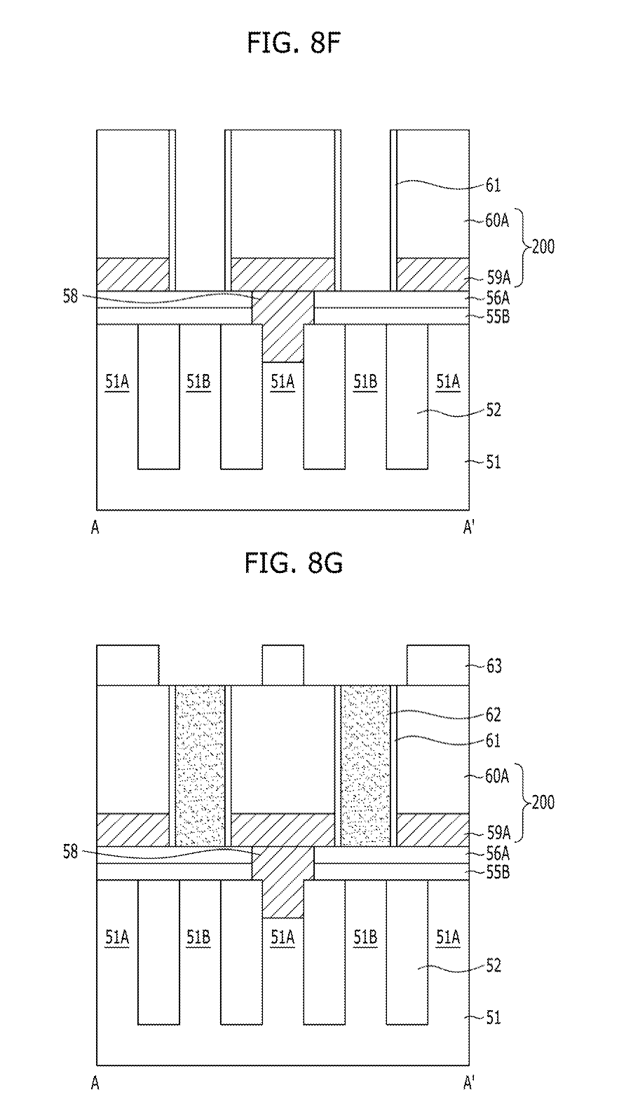

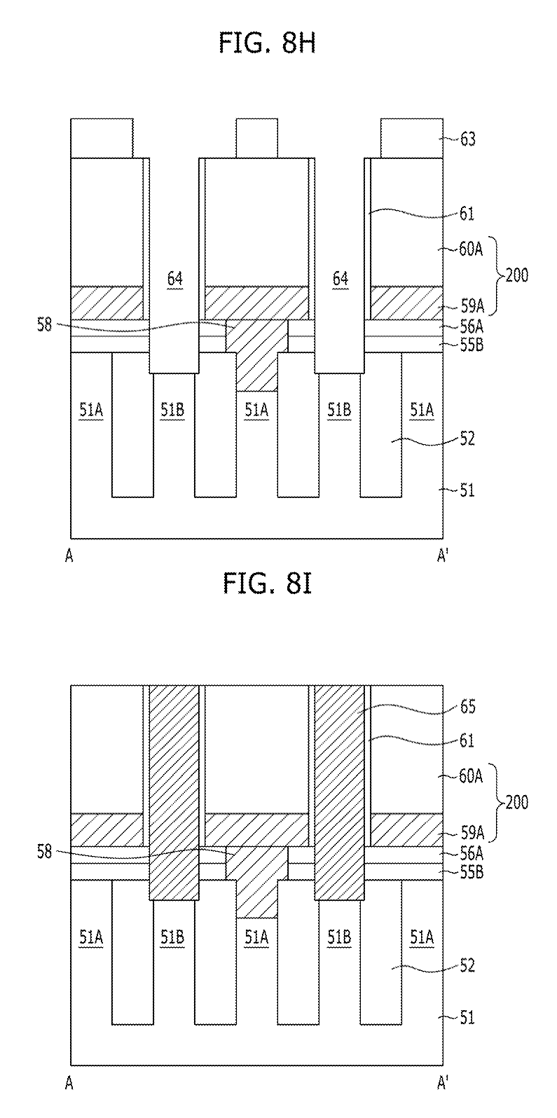

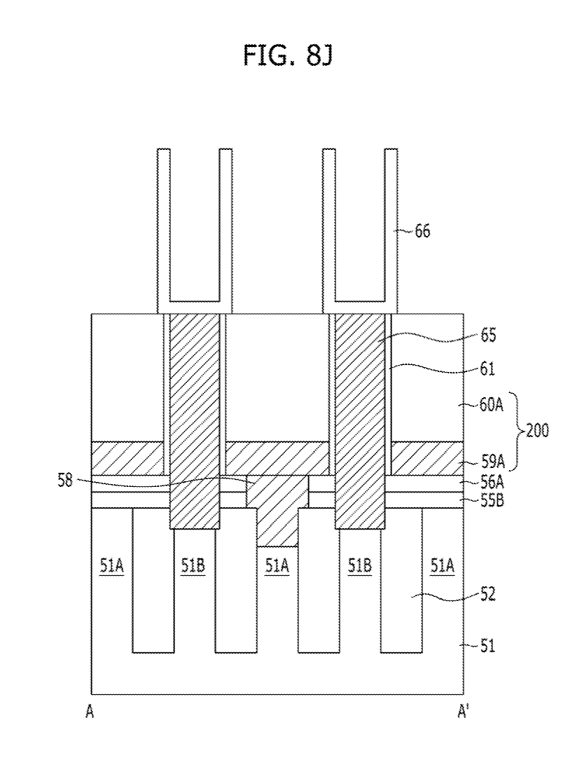

FIGS. 8A to 8J are cross-sectional views illustrating a method for fabricating the semiconductor device in accordance with another embodiment of the present invention taken along the A-A′ direction illustrated in FIG. 1.

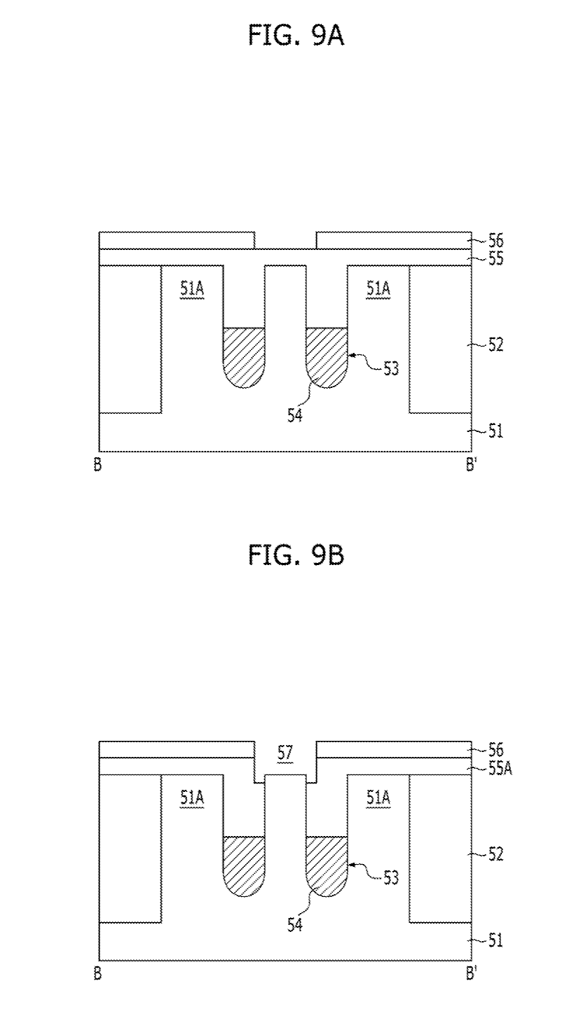

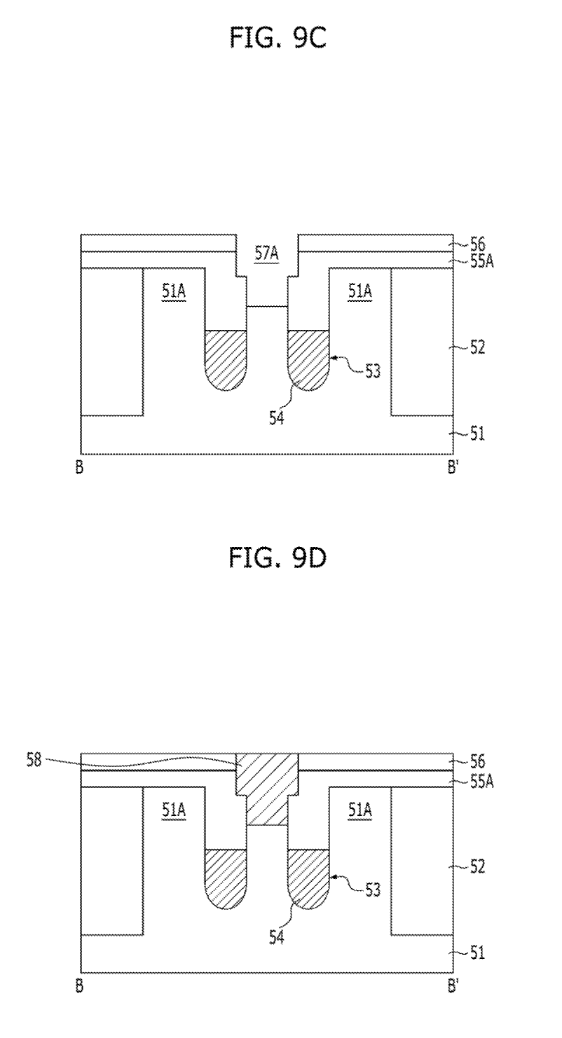

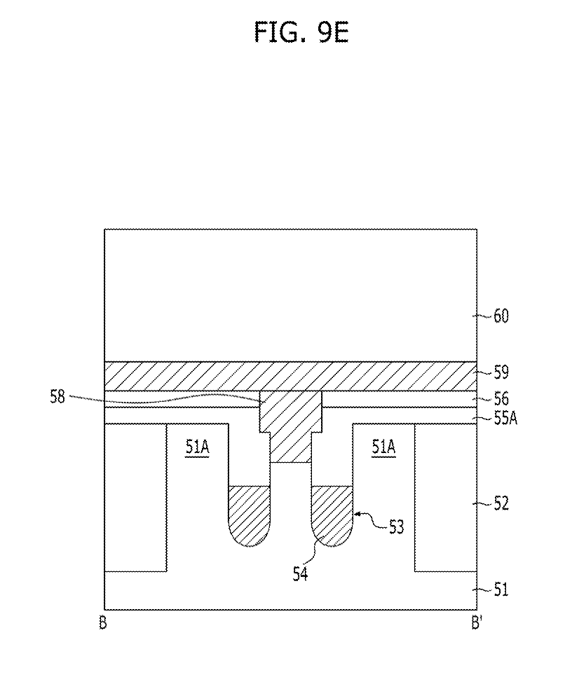

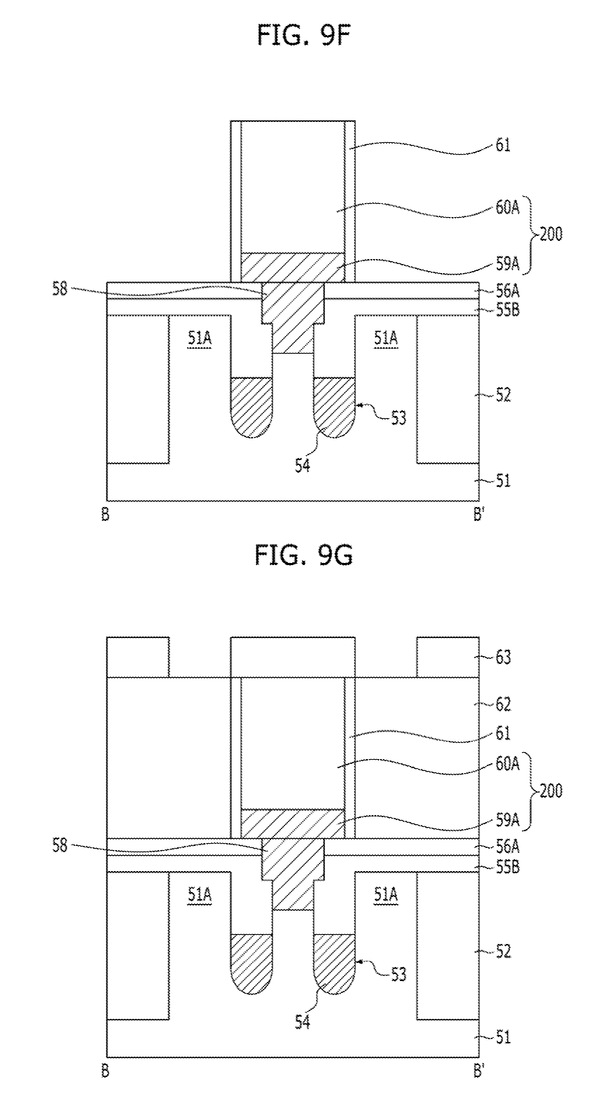

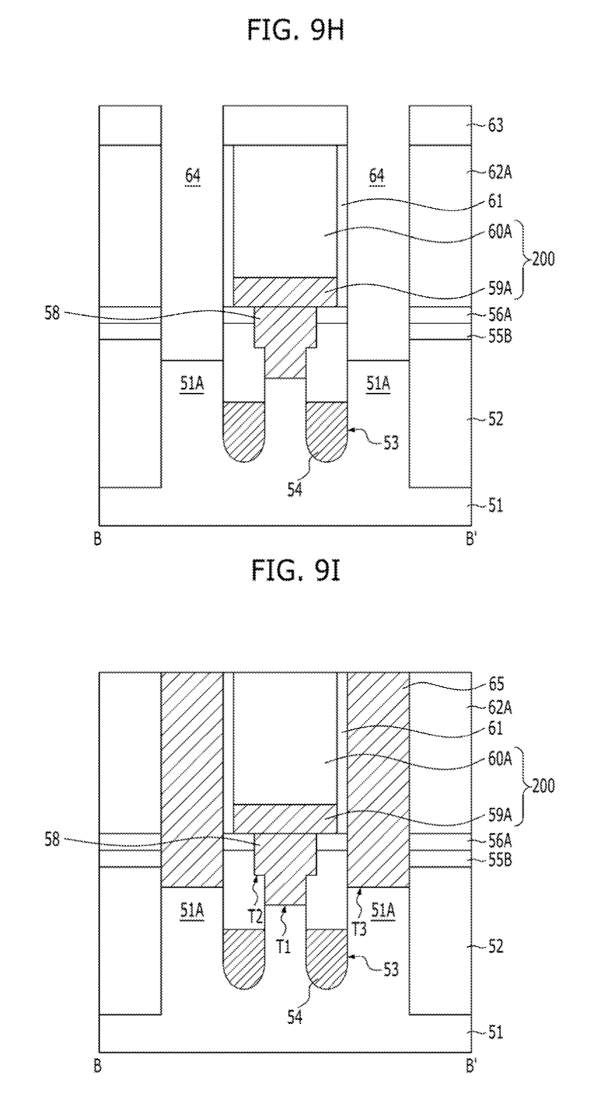

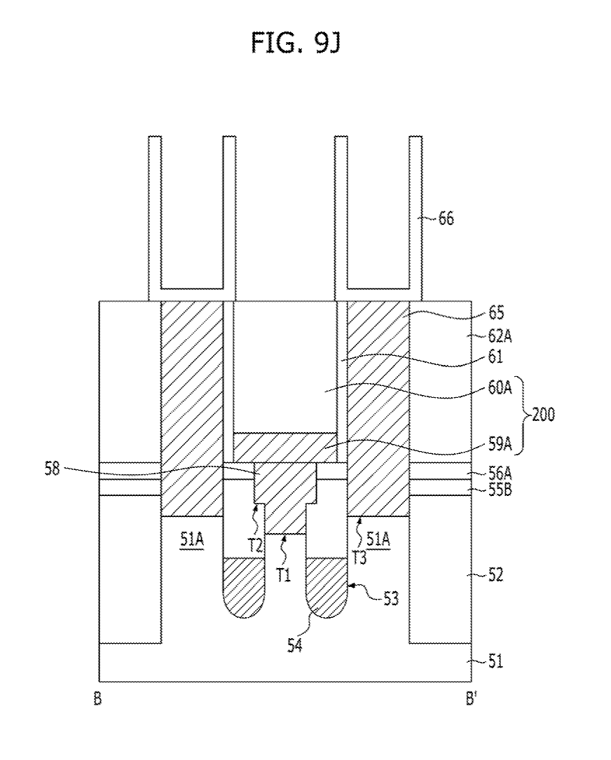

FIGS. 9A to 9J are cross-sectional views illustrating the method for fabricating the semiconductor device in accordance with another embodiment of the present invention taken along the B-B′ direction illustrated in FIG. 1.

In order to promote a better understanding, FIGS. 8A to 8J and FIGS. 9A to 9J will be described together. The steps of FIGS. 8A to 8J and the steps of FIGS. 9A to 9J are performed according to the same process sequence, and like reference numerals refer to like components.

Referring FIGS. 8A and 9A, an isolation layer 52 is formed in the semiconductor substrate 51 to define active regions 51A and 51B. The semiconductor substrate 51 may be a silicon substrate or a silicon germanium substrate. The isolation layer 52 may be formed through the STI process.

Then, the semiconductor substrate 51 is etched to form a trench 53. The trench 53 serves to provide the buried gate formation region. A pair of trenches 53 may be formed. The active region 51A is disposed between the pair of trenches 53, and the active region 51B is disposed between the trench 53 and the isolation layer 52. That is, the first active region 51A may be disposed between the pair of trenches 53 and between the pair of second active regions 51B.

A buried gate electrode 54 is formed to fill a part of the trench 53. Before the buried gate electrode 54 is formed, a gate dielectric layer (not illustrated) may be formed on the sidewalls and bottom of the trench 53.

The buried gate electrode 54 may be formed through the following process: a conductive material is formed to fill the trench 53, planarized until the semiconductor substrate 51 is exposed, and then recessed to a predetermined depth. The conductive material may serve as an electrode. The conductive material may be a low-resistance material such as tungsten, for example. Alternatively, the conductive material may be a stacked structure of a diffusion barrier layer and a metal layer. For example, the diffusion barrier layer may be a titanium-containing material, and the metal layer may include a low resistance metal. The titanium-containing material may be TiN, for example.

A sealing layer 55 is formed over the buried gate electrode 54 to fill the rest of the trench 53. The sealing layer 55 serves to protect the buried gate electrode 54 from being oxidized and attacked during a subsequent process and may include an insulating material. For example, the sealing layer 55 may be a nitride material. The sealing layer 55 may be formed to such a thickness to fill the trench 53 and may be formed even over the semiconductor substrate 51. As disclosed above, together the buried gate electrode 54 and the sealing layer 55 define the buried gate structure.

A hard mask pattern 56 is formed over the sealing layer 55, The hard mask pattern 56 is patterned to open a bit line contact region. That is, the hard mask pattern 56 may be patterned to define a bit line contact hole, and the bit line contact region may include an active region between the adjacent buried gate electrodes 54. The hard mask pattern 56 may be an insulating material having an etching selectivity with respect to the sealing layer 55 and the semiconductor substrate 51. For example, the hard mask pattern 56 may be an oxide material such as silicon oxide.

Referring to FIGS. 8B and 96, a first contact hole 57 is formed by etching the sealing layer 55 using the hard mask pattern 56 as an etch barrier. The first contact hole 57 may include a region for forming a bit line contact that is a bit line contact hole. The etching process for forming the first contact hole 57 may be performed until the first active region 51A is exposed.

The sealing layer 55 may be etched under a condition in which an etch ratio of oxide to nitride is 1:2 to 4. For example, when assuming that an etch rate of oxide per second ranges from 7 Å to 13 Å, the etching process may be performed under a condition in which an etch rate of nitride per second ranges 20 Å to 40 Å. The above-described numerical values are only examples for promoting understanding of the present embodiment and may be changed according to the conditions and requirements of the respective processes.

The sealing layer 55 may be etched through one single gas or a mixture of two or more gases selected from the group consisting of CF₄, CHF₃, CH₃F, and CH₂F₂. A mixture of Ar, He, and O₂ may be added to the single gas or the gas mixture.

The etched sealing layer 55 is represented by reference numeral 55A. In the second embodiment, the first contact hole 57 may have a larger CD than the first active region 51A between the buried gate structures. Furthermore, while the sealing layer 55A is etched, the etched surface of the sealing layer 55A may be maintained at a lower level than the surface of the first active region 51A through over-etching.

Referring to FIGS. 8C and 9C, the first active region 51A exposed at the bottom of the first contact hole 57 is etched to a predetermined depth. When the first active region 51A is etched, the etching condition may be controlled to minimize a loss of the sealing layer 55A exposed at both sides of the first contact hole 57. That is, the first active region 51A may be etched under a condition in which the etch ratio of nitride and/or oxide to silicon is 1:10 to 20. For example, when supposing that the etch rate of nitride and/or oxide per second range from 70 Å to 130 Å, the etching process may be performed under a condition in which the etch rate of silicon per second ranges from 1,000 Å to 1,800 Å.

When the first active region 51A is additionally etched under such a condition that the etch rate of nitride and/or oxide is much lower than the etch rate of silicon, a loss of the exposed sealing layer 55A may be minimized. The above-described numerical values are only examples for promoting understanding and may be changed according to the conditions and requirements of the respective processes.

The first active region 51A may be etched through a gas mixture of HBr, Cl₂, O₂, He, and SF₆. In order to maximize an etching selectivity difference, bias power may not be applied, but, for example, only source power may be applied to perform the etching process.

The first active region 51A may be etched to such a depth as not to expose the buried gate electrode 54. The depth of the first contact hole 57 may be defined in consideration of a thickness loss of the semiconductor substrate 51 when a storage node contact hole is formed during a subsequent process. The depth of the first contact hole 57 may be larger than the thickness of the semiconductor substrate 51, which may be lost when the storage node contact hole is formed.

The first contact hole 57A having a larger depth is farmed due to etching of the first active region 51A.

Referring to FIGS. 8D and 9D, a first plug 58 is formed to fill the first contact hole 57A and contacts the first active region 51A. The first plug 58 may include the bit line contact for connecting the semiconductor substrate 51 and the bit line structure to be subsequently formed. The first plug 58 may be a conductive material.

Referring to FIGS. 8E and 9E, a conductive layer 59 is formed over the first plug 58 and the hard mask pattern 56. In an embodiment, the first plug 58 and the conductive layer 59 are formed separately from each other. In another embodiment, the first contact hole 57A of FIG. 8C may be filled also with the conductive layer 59 instead of the first plug 58. The conductive layer 59 filled in the first contact hole 57A and over the hard mask pattern 56 may form the first plug 58 and a bit line electrode 59A to be subsequently formed.

A bit line hard mask layer 60 is formed over the conductive layer 59. The bit line hard mask layer 60 may serve as an etch barrier and an insulating layer between an upper layer and a bit line during a bit line formation process. The bit line hard mask layer 60 may be a nitride material such as silicon nitride.

Referring to FIGS. 8F and 9F, the bit line hard mask layer 60 and the conductive layer 59 illustrated in FIGS. 8E and 9E are etched to form a bit line structure 200. The etched bit line hard mask layer 60 and the etched conductive layer 59 define the bit line hard mask 60A and the bit line electrode 59A, respectively. Together the bit line hard mask 60A and the bit line electrode 59A define the bit line structure 200.

The spacer 61 is formed on the sidewalls of the bit line structure 200. The spacer 61 may serve to protect the sidewalls of the bit line structure 200 and insulate storage node contacts to be subsequently formed. For example, the spacer 61 may be an insulating material or a nitride material such as silicon nitride.

Referring to FIGS. 8G and 9G, an interlayer dielectric layer 62 is formed to fill the space between the bit line structures 200. The interlayer dielectric layer 62 may be formed through the following process: an insulating material is formed to fill the space between the bit line structures 200 and planarized until the top surface of the bit line structure 200 is exposed. The planarization may be performed through a chemical mechanical polishing (CMP) process or an etch-back process. The insulating material may be an oxide material such as silicon oxide, for example.

A mask pattern 63 is formed over the bit line structure 200 and the interlayer dielectric layer 62. The mask pattern 63 may be formed by applying a photoresist layer onto the bit line structure 200 and the interlayer dielectric layer 62 and by patterning the photoresist layer through exposure and development to open a storage node contact region. In the A-A′ direction, where a margin between the storage node contacts is small, the mask pattern 63 may be formed with a larger CD than at least the CD of the space between the bit line structures 200.

Referring to FIGS. 8H and 9H, a second contact hole 64 that exposes the second active region 51B is formed by selectively etching the interlayer dielectric layer 62, the hard mask pattern 56, and the sealing layer 55A between the bit line structures 200 using the mask pattern 63 as an etching barrier. The second contact hole 64 may be the storage node contact hole for forming a storage node contact.

In the A-A′ direction, where the mask pattern 63 is formed with a lager CD than the CD of the space between the bit line structures 200, the bit line hard mask 60A made of nitride may be used as an etch barrier to perform a self-aligned contact etch process. The self-aligned contact etch process refers to an etch process using a gas that selectively etches, for example, only oxide while having an etching selectivity with respect to nitride. Thus, for example, only the interlayer dielectric layer 62 may be selectively etched without a loss of the bit line hard mask 60A. In order to form the second contact hole 64 that exposes the second active region 51B, the sealing layer 55A made of nitride and formed over the semiconductor substrate 51 is etched. However, since the sealing layer 55A is sufficiently thin, loss of the bit line hard mask 60A is not serious.

When the second contact hole 64 is formed, the second active region 51B of the semiconductor substrate 51 may be additionally etched to a predetermined depth to reduce interfacial resistance between the storage node contact and the second active region 51B. When the second active region 51B is additionally etched, a contact area between the storage node contact and the second active region 51B may increase while the bottom and sidewalls of the storage node contact partially contact the second active region 51B. Thus, the interfacial resistance may be reduced.

The depth to which the second active region 51B is additionally etched may be adjusted to not exceed the depth to which the first active region 51A is additionally etched when the bit line contact hole is formed.

The etched interlayer dielectric layer 62, the etched hard mask pattern 56, and the etched sealing layer 55A are represented by 62A, 56A, and 55B, respectively.

Referring to FIGS. 8I and 9I, the second plug 65 is formed to fill the second contact hole 64. The second plug 65 may be formed through the following process: a conductive material is formed to fill the second contact hole 64 and then planarized until the top surface of the interlayer dielectric layer 62A is exposed. The planarization process may be a CMP process or an etch-back process.

Before the second plug 65 is formed, a spacer (not illustrated) may be additionally formed on the sidewalls of the second contact hole 64.

As the loss of the sealing layer 55B is minimized during an additional etching process for the second active region 516 and the second plug 65 is shallower than the first plug 58 in the semiconductor substrate 51, the top surface T1 of the first active region 51A may be lower than the top surface T2 of the buried gate structure and the top surface T3 of the second active region 516. Thus, a margin between the buried gate electrode 54 and the first plug 58 may be secured, and a margin between the second plug 65 and the adjacent first active region 51A may be secured. Therefore, it is possible to prevent a short in each case.

Referring to FIGS. 8J and 9J, a storage electrode 66 is formed over the interlayer dielectric layer 62A to connect to the second plug 65. The storage electrode 66 may include a stacked structure of a bottom electrode, a dielectric layer, and a top electrode. The storage electrode 66 is formed in a cylinder type but may be formed in a pillar type, a concave type, a plate type, or a stack type.

In the present embodiment, the first plug and the second plug are formed to be aligned with each other. However, as the top surface of the first active region contacting the bit line contact is lower than the top surface of the second active region contacting the storage node contact, a margin between the storage node contact and the adjacent first active region may be secured. Thus, it is possible to prevent a short between the adjacent active regions even though the storage node contacts are misaligned. Furthermore, as the loss of the buried gate structure is minimized when the bit line contact hole is formed, it is possible to prevent a short between the buried gate and the bit line contact even though an unetch phenomenon occurs when the buried gate is formed.

Although various embodiments have been described for illustrative purposes, it will be apparent to those skilled in the art that various changes and modifications may be made without departing from the spirit and scope of the invention as defined in the following claims.

What is claimed:

1. A semiconductor device comprising:
a substrate comprising a first active region and second active regions;
a bit line structure in contact with the first active region; and
storage node contacts in contact with the second active regions,
wherein a top surface of the first active region is lower than top surfaces of the second active regions.

2. The semiconductor device of claim 1, wherein the bit line structure comprises a bit line contact, a bit line electrode, a bit line hard mask, and spacers, the spacers being formed on sidewalls of the bit line structure.

3. The semiconductor device of claim 1, wherein the first active region is disposed between adjacent second active regions.

4. The semiconductor device of claim 1, wherein the substrate further comprises a buried gate structure.

5. The semiconductor device of claim 2, wherein the bit line contact has a critical dimension (CD) equal to that of the first active region.

6. A semiconductor device comprising:
a substrate comprising buried gate structures, a first active region formed between the buried gate structures, and second active regions, the second active regions in contact with one sides of the buried gate structures and arranged symmetrically with each other;
a bit line structure in contact with the first active region; and
storage node contacts in contact with the second active regions,
wherein a top surface of the first active region is lower than top surfaces of the second active regions and top surfaces of the buried gate structures.

7. The semiconductor device of claim 6, wherein the buried gate structures comprise a stacked structure of a buried gate electrode and a sealing layer.

8. The semiconductor device of claim 7, wherein a top surface of the sealing layer is higher than the top surface of the first active region.

9. The semiconductor device of claim 6, wherein the bit line structure comprises a bit line contact, a bit line electrode, a bit line hard mask, and spacers, the spacers being formed on sidewalls of the bit line structure.

10. The semiconductor device of claim 6, wherein the first active region is disposed between adjacent second active regions.

11. The semiconductor device of claim 9, wherein the bit line contact has a larger CD than that of the first active region.
